(19) United States
(12) Patent Application Publication
(10) Pub. No.: US 2011/0060431 A1
(43) Pub. Date: Mar. 10, 2011

(54) AUDIO OUTPUT DEVICES

(75) Inventor: Chih-Haur Huang, Tainan County (TW)

(73) Assignee: HIMAX MEDIA SOLUTIONS, INC., Tainan County (TW)

(21) Appl. No.: 12/555,922

(22) Filed: Sep. 9, 2009

(51) Int. Cl. G06F 17/00; H03M 1/12

(52) U.S. Cl. 700/94; 341/155

(57) ABSTRACT

An audio output device is provided and includes a signal source, a detector, a plurality of digital-to-analog converters, and a plurality of amplifiers. The signal source generates a plurality of digital signals. The detector receives the digital signals and detects states of the digital signals to generate a plurality of control signals according to the detection results respectively. The digital-to-analog converters receive the digital signals and convert the digital signals to a plurality of analog signals, respectively. The amplifiers receive the analog signals and generate a plurality of amplified signals according to the control signals, respectively.

### BACKGROUND OF THE INVENTION

1. Field of the Invention

The invention relates to an audio output device, and more particularly to an audio output device for reducing crosstalk between audio output paths.

2. Description of the Related Art

FIG. 1 shows a conventional audio output device. A conventional audio output device 1 comprises a signal source 10, a plurality of digital-to-analog converters (DACs) 11, a plurality of amplifiers 12, and a plurality of speakers 13. In FIG. 1, two DACs 11₁-11₂, two amplifiers 12₁ and 12₂, and two speakers 13₁ and 13₂ are given as an example. One set of the DAC 11₁, the amplifier 12₁, and the speaker 13₁ forms one audio output path, and the other set of the DAC 11₂, the amplifier 12₂, and the speaker 13₂ forms the other audio output path. The signal source 10 generates two digital signals S10₁ and S10₂ to the DACs 11₁ and 11₂ respectively. The DACs 11₁ and 11₂ convert the received digital signals S10₁ and S10₂ to analog signals S11₁ and S11₂ respectively. The amplifiers 12₁ and 12₂ receive the analog signals S11₁ and S11₂ and amplify analog signals S11₁ and S11 to generate amplified signals S12₁ and S12₂, respectively. The speakers 13₁ and 13₂ produce sound according to the amplified signals S12₁ and S12₂ respectively.

Assume that the digital signal S10₁ is continuously switched between a high logic level and a low logic level, while the digital signal S10₂ is continuously at a constant logic level, such as the low logic level (that is the audio output path corresponding to the digital signal S10₂ is at a mute mode). In this case, the speaker 13₁ produces sound according to the amplified signal S12₁ derived from the digital signal S10₁. Further, the speaker 13₂ should not produce sound according to the amplified signal S12₂ derived from the digital signal S10₂. However, since the DACs 11₁ and 11₂, the amplifiers 12₁ and 12₂, and the speakers 13₁ and 13₂ of the two audio output paths use the same reference voltage and the same power source, crosstalk is generated between the two audio output paths, so that the speaker 13₂ undesirably products noises from the other audio output path.

Thus, it is desired to provide an audio output device which can prevent an audio output path at a mute mode from being influenced by crosstalk.

### BRIEF SUMMARY OF THE INVENTION

An exemplary embodiment of an audio output device comprises a signal source, a detector, a plurality of digital-to-analog converters, and a plurality of amplifiers. The signal source generates a plurality of digital signals. The detector receives the digital signals and detects states of the digital signals to generate a plurality of control signals according to the detection results respectively. The digital-to-analog converters receive the digital signals and convert the digital signals to a plurality of analog signals, respectively. The amplifiers receive the analog signals and generate a plurality of amplified signals according to the control signals, respectively.

In an embodiment, when the detector detects that at least one of the digital signals is in a predetermined state, the detector controls the corresponding amplifier according to the corresponding control signal to not generate the amplified signal.

In another embodiment, when the detector detects that the at least one digital signal is in the predetermined state, the detector further controls the corresponding digital-to-analog converter according to the corresponding control signal to not generate the analog signal.

A detailed description is given in the following embodiments with reference to the accompanying drawings.

### BRIEF DESCRIPTION OF THE DRAWINGS

The invention can be more fully understood by reading the subsequent detailed description and examples with references made to the accompanying drawings, wherein:

FIG. 1 shows a conventional audio output device;

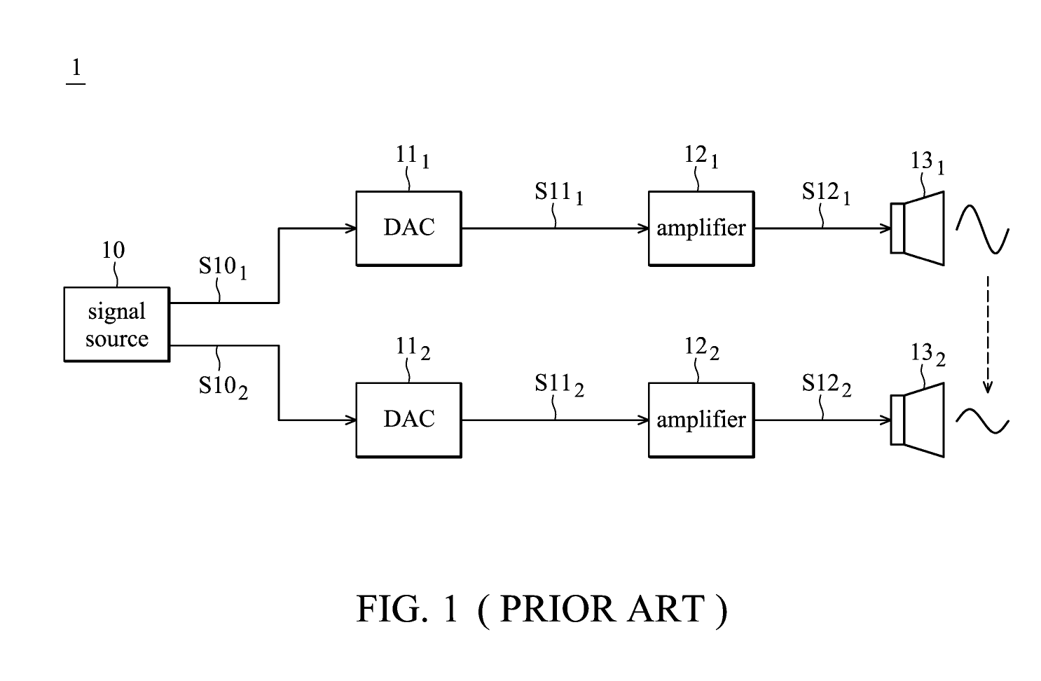

FIG. 2 shows an exemplary embodiment of an audio output device;

FIG. 3 shows an exemplary embodiment of the detector in FIG. 2;

FIG. 4 shows an exemplary embodiment of the detection unit in FIG. 3;

FIG. 5 shows an exemplary embodiment of the amplifiers in FIG. 2;

FIG. 6 shows another exemplary embodiment of an audio output device; and

FIG. 7 shows another exemplary embodiment of an audio output device.

### DETAILED DESCRIPTION OF THE INVENTION

The following description is of the best-contemplated mode of carrying out the invention. This description is made for the purpose of illustrating the general principles of the invention and should not be taken in a limiting sense. The scope of the invention is best determined by reference to the appended claims.

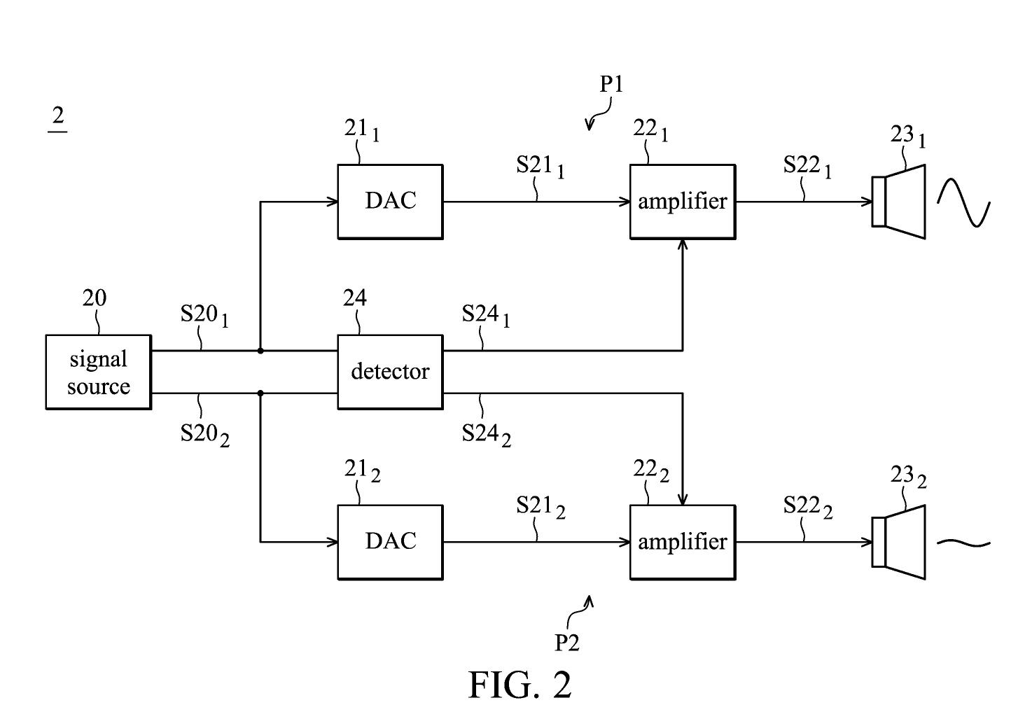

Audio output devices are provided. In an exemplary embodiment of an audio output device in FIG. 2, an audio output device 2 comprises a signal source 20, a plurality of digital-to-analog converter (DACs) 21, a plurality of amplifiers 22, a plurality of speakers 23, and a detector 24. In practice, the numbers of DACs 21, amplifiers 22, and speakers 23 are determined according to system requirements. However, in the embodiment of FIG. 2, two DACs 21₁ and 21₂, two amplifiers 22₁ and 22₂, and two speakers 23₁ and 23₂ are given as an example. One set of the DAC 21₁, the amplifier 22₁, and the speaker 23₁ forms one audio output path P1, and the other set of the DAC 21₂, the amplifier 22₂, and the speaker 23₂ forms the other audio output path P2.

Referring to FIG. 2, the signal source 20 generates a digital signal S20₁ for the DAC 21₁ of the audio output path P1, while the signal source 20 further generates a digital signal S20₂ for the DAC 21₂ of the audio output path P2. The DACs 21₁ and 21₂ receive the digital signals S20₁ and S20₂ respectively. The DAC 21₁ converts the received digital signal S20₁ to an analog signal S21₁, and the DAC 21₂ converts the received digital signal S20₂ to an analog signal S21₂. The amplifiers 22₁ and 22₂ receive the analog signals S21₁ and S21₂ respectively. The amplifier 22₁ amplifies the analog signal S21₁ and generates an amplified signal S22₁ according to a control signal S24₁. The amplifier 22₂ amplifies the analog signal S21₂ and generates an amplified signal S22₂ according to a control signal S24₂. The speakers 23₁ and 23₂ receive the amplified signals S22₁ and S22₂ and produce sound according to the amplified signals S22₁ and S22₂, respectively. In the embodiment, the control signals S24₁ and S24₂ for controlling the amplifiers 22₁ and 22₂ are generated by the detector 24. The detector 24 receives the digital signals S20₁ and S20₂. The detector 24 detects states of the digital signals S20₁ and S20₂ and generates the control signals S24₁ and S24₂ according to the detection result related to the digital signals S20₁ and S20₂ respectively.

A digital signal generated by the signal source 20 may be continuously switched between a high logic level and a low logic level or in a predetermined state. In the embodiment, a digital signal generated by the signal source 20 in the predetermined state means that the digital signal is continuously at a constant logic level, such as a low logic level, for a predetermined time, wherein the predetermined time is determined according to system setting or specification. When a digital signal generated by the signal source 20 is continuously switched between a high logic level and a low logic level, the corresponding audio output path produces sound according to the corresponding amplified signal. When a digital signal generated by the signal source 20 is continuously at a constant logic level for a predetermined time (in the predetermined state), the corresponding audio output path does not produce sound according to the corresponding amplified signal; in other words, the corresponding audio output path is at a mute mode.

Thus, by detecting the states of the digital signals S20₁ and S20₂, the detector 24 can determine whether the audio output paths P1 and P2 are at a mute mode. The detector 24 generates the control signals S24₁ and S24₂ according to the detection result to control the amplifiers 22₁ and 22₂ to generate the amplified signals S22₁ and S22₂ or not, respectively. The process for the detector 24 to control the amplifiers 22₁ and 22₂ will be described in the following.

Assume that the digital signal S20₁ is continuously switched between a high logic level and a low logic level, while the digital signal S20₂ is continuously at the low logic level for a predetermined time (in the predetermined state). Thus, the audio output path P2 is at a mute mode. The detector 24 detects that the digital signal S20₁ is continuously switched between the high logic level and the low logic level and de-asserts the control signal S24₁ according to the detection result. The detector 24 controls the amplifier 22₁ of the audio output path P1 according to the de-asserted control signal S24₁, and the amplifier 22₁ generates the amplified signal S22₁ according to the analog signal S21₁ derived from the digital signal S20₁. Then, the speaker 23₁ of the audio output path P1 produces sound according to the amplified signal S22₁. On the contrary, the detector 24 detects that the digital signal S20₂ is continuously at the low logic level (in the predetermined state) and asserts the control signal S24₂ according to the detection result. The detector 24 controls the amplifier 22₂ of the audio output path P2 according to the asserted control signal S24₂, and the amplifier 22₂ does not generate the amplified signal S22₂ according to the analog signal S21₂ derived from the digital signal S20₂. Thus, the speaker 23₂ does not receive any signal from the amplifier 22₂ and does not produce sound.

According to the above embodiment, when the audio output path P2 is at the mute mode, the detector 24 controls the amplifier 22₂ of the audio output path P2 to not generate the amplified signal S22₂. Since the speaker 23₂ of the audio output path P2 does not receive the signal from the amplifier 22₂, the sound derived from the audio output path P1 is not transferred to the speaker 23₂. Thus, crosstalk generated between the audio output paths P1 and P2 is minimized, reducing the noises produced by the speaker 23₂.

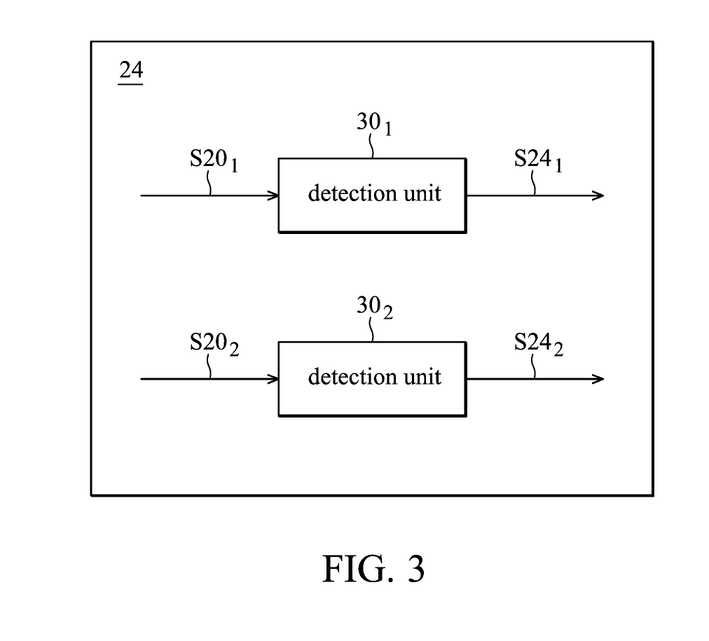

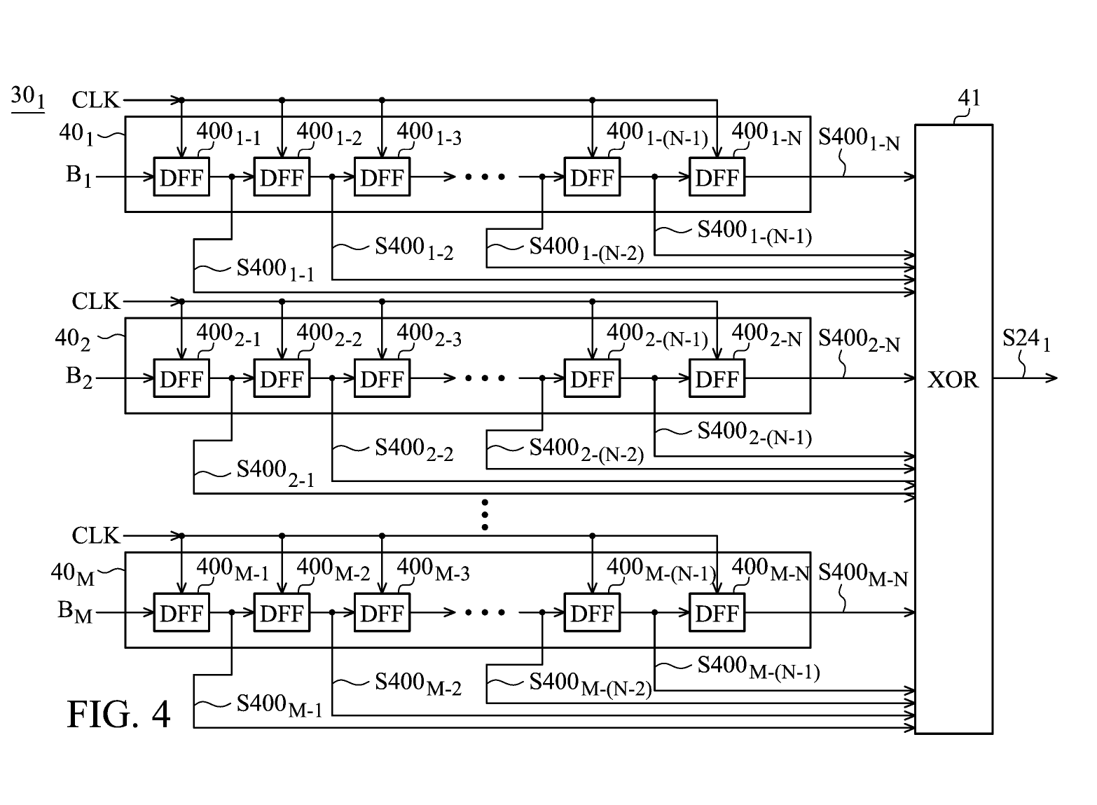

FIG. 3 shows an exemplary embodiment of the detector 24 in FIG. 2. Referring to FIG. 3, the detector 24 comprises two detection units 30₁ and 30₂. In the embodiment, the number of detection units is equal to the number of audio output paths. The detection units 30₁ and 30₂ detect the states of the digital signals S20₁ and S20₂ and generate the control signals S24₁ and S24₂, respectively. Referring to FIG. 4, each of the detection units 30₁ and 30₂ comprises a plurality of delay circuits 40 and a logic gate 41. In the following, the detection unit 30₁ is given as an example for description. Assume that the digital signal S20₁ generated by the signal source 20 has M bits B₁-B_{M}. Thus, the detection unit 30₁ comprises M delay circuits 40₁˜40_{M} for respectively receiving the bits B₁-B_{M} of the digital signal S20₁. Each of the delay circuits 40₁˜40_{M} comprises N D-type flip-flops (DFFs) 400 which is coupled in series and controlled by a clock signal CLK. In one delay circuit, the first D-type flip-flop among the D-type flip-flops receives the corresponding bit of the digital signal S20₁, and each D-type flip-flops generates a delay signal according to the corresponding bit. For example, the delay circuit 40₁ receives the first bit B₁ of the digital signal S20₁ and comprises N D-type flip-flops 400₁₋₁˜400_{1-N}. The first D-type flip-flop 400₁₋₁ receives the bit B₁. The D-type flip-flops 400₁₋₁˜400_{1-N} generate the delay signals S400₁₋₁˜S400_{1-N} in response to the bit B₁ of the digital signal S20₁ respectively. Similarly, in the delay circuit 40₂, the D-type flip-flop 400₂₋₁ receives the bit B₂ of the digital signal S20₁, and the D-type flip-flops 400₂₋₁˜400_{2-N} generate the delay signals S400₂₋₁˜S400_{2-N} in response to the bit B₂; in the delay circuit 40_{M}, the D-type flip-flop 400_{M-1} receives the bit B_{M} of the digital signal S20₁, and the D-type flip-flops 400_{M-1}˜400_{M-N} generate the delay signals S400_{M-1}˜S400_{M-N} in response to the bit B_{M}.

In the embodiment, the logic gate 41 is implemented by an exclusive OR (XOR) gate. The XOR gate 41 receives the delay signals S400₁₋₁˜S400_{1-N}, S400₂₋₁˜S400_{2-N}, . . . S400_{M-1}˜S400_{M-N} and generates the control signal S24₁ according to the delay signals S400₁₋₁˜S400_{1-N}, S400₂₋₁˜S400_{2-N}, . . . S400_{M-1}˜S400_{M-N}. According to the logic operation of the XOR gate 41, when the digital signal S20₁ is switched between the high logic level and the low logic level, the XOR gate 41 generates the control signal S24₁ with a high level; that is the control signal S24₁ is de-asserted. On the contrary, when the digital signal S20₁ is continuously at the low logic level, the XOR gate 41 generates the control signal S24₁ with a low level; that is the control signal S24₁ is asserted. Then, whether the amplifier 22₁ generates the amplified signal S22₁ is determined according to the control signal S24₁.

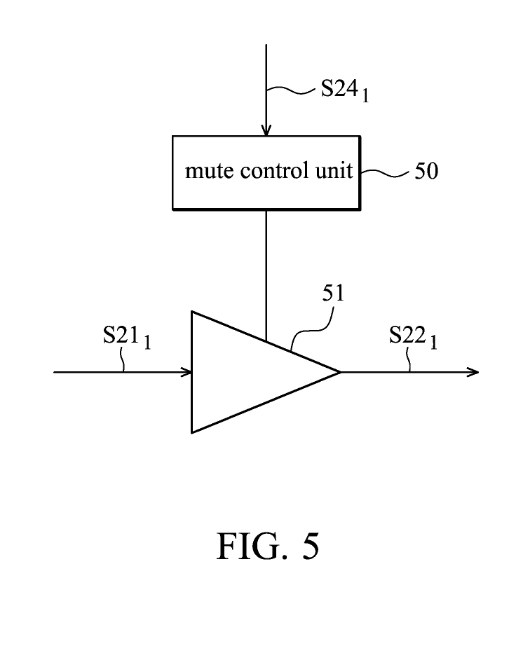

Referring to FIG. 5, in the embodiment, each of the amplifiers 22₁ and 22₂ may comprise a mute control unit 50 and an amplifying unit 51. In the following, the amplifier 22₁ is given as an example for description. The mute control unit 50 is controlled by the detector 24, in other words, whether the mute control unit 50 is enabled by the detector 24 is determined according to the control signal S24₁. The amplifying unit 51 receives the analog signal S21₁ and amplifies the analog signal S21₁ to generate the amplified signal S22₁. When receiving the de-asserted control signal S24₁, the mute control unit 50 is disabled, so that the amplifying unit 51 can amplify the analog signal S21₁ to generate the amplified signal S22₁ for the speaker 23₁. On the contrary, when receiving the asserted control signal S24₁, the mute control unit 50 is enabled, so that the amplifying unit 51 is disabled by the mute control unit 50 and stops generating the amplified signal S22₁ for the speaker 23₁.

According to the above assumptions, since the digital signal S20₁ is switched between the high logic level and the low logic level, the XOR gate 41 of the detection unit 30₁ generates the de-asserted control signal S24₁, and the mute control unit 50 of the amplifier 22₁ is disabled, so that the amplifying unit 51 of the amplifier 22₁ can amplify the analog signal S21₁ to generate the amplified signal S22₁ for the speaker 23₁. Further, since the digital signal S20₂ is continuously at the low logic level, the XOR gate 41 of the detection unit 30₂ generates the asserted control signal S24₂, and the mute control unit 50 of the amplifier 22₂ is enabled, so that the amplifying unit 51 of the amplifier 22₂ is disabled by the mute control unit 50 and stops generating the amplified signal S22₂ for the speaker 23₂.

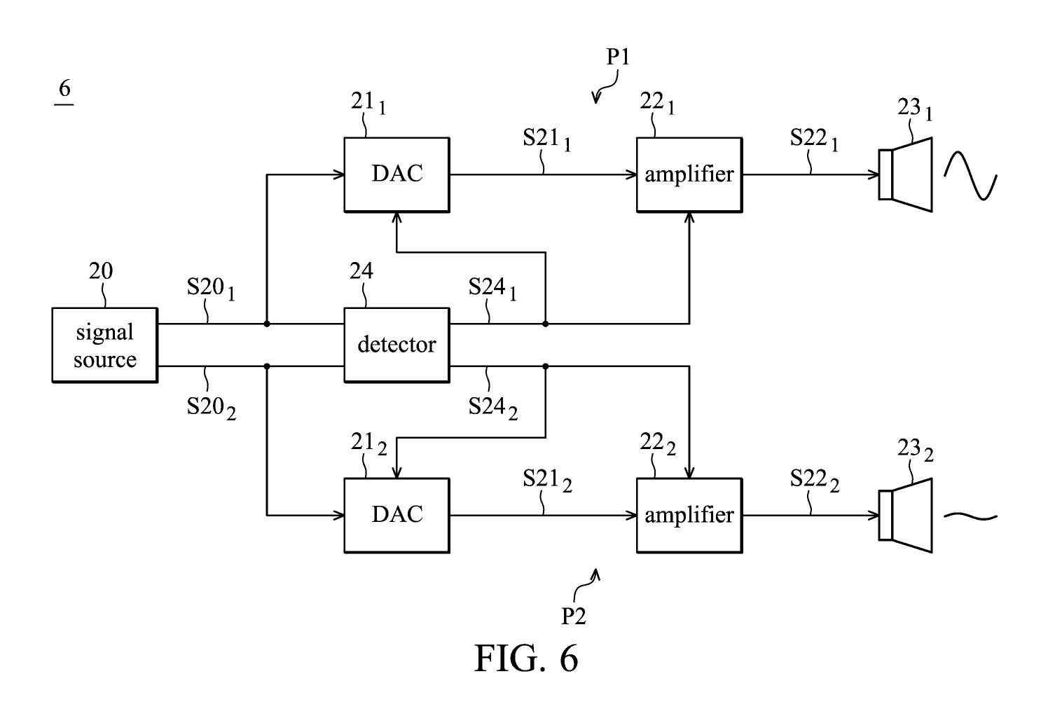

FIG. 6 shows another exemplary embodiment of an audio output device. An audio output device 6 in FIG. 6 is similar as the audio output device 2. The difference between the audio output devices 2 and 6 is that the control signal S24₁ in FIG. 6 further controls the DAC 21₁ in the audio output path P1 and that the control signal S24₂ in FIG. 6 further controls the DAC 21₂ in the audio output path P2.

In the above assumptions, since the digital signal S20₁ is switched between the high logic level and the low logic level, the detector 24 generates the de-asserted control signal S24₁, so that the DAC 21₁ generates the analog signal S21₁ according to the de-asserted control signal S24₁, and the amplifier 22₁ generates the amplified signal S22₁ according to the de-asserted control signal S24₁. Since the digital signal S20₂ is at the predetermined state (being continuously at the low logic level), the detector 24 generates the asserted control signal S24₂, so that the DAC 21₂ does not generate the analog signal S21₂ according to the asserted control signal S24₂, and the amplifier 22₂ does not generate the amplified signal S22₂ according to the asserted control signal S24₂. Thus, in the embodiment of FIG. 6, crosstalk generated between the audio output paths P1 and P2 is much degraded.

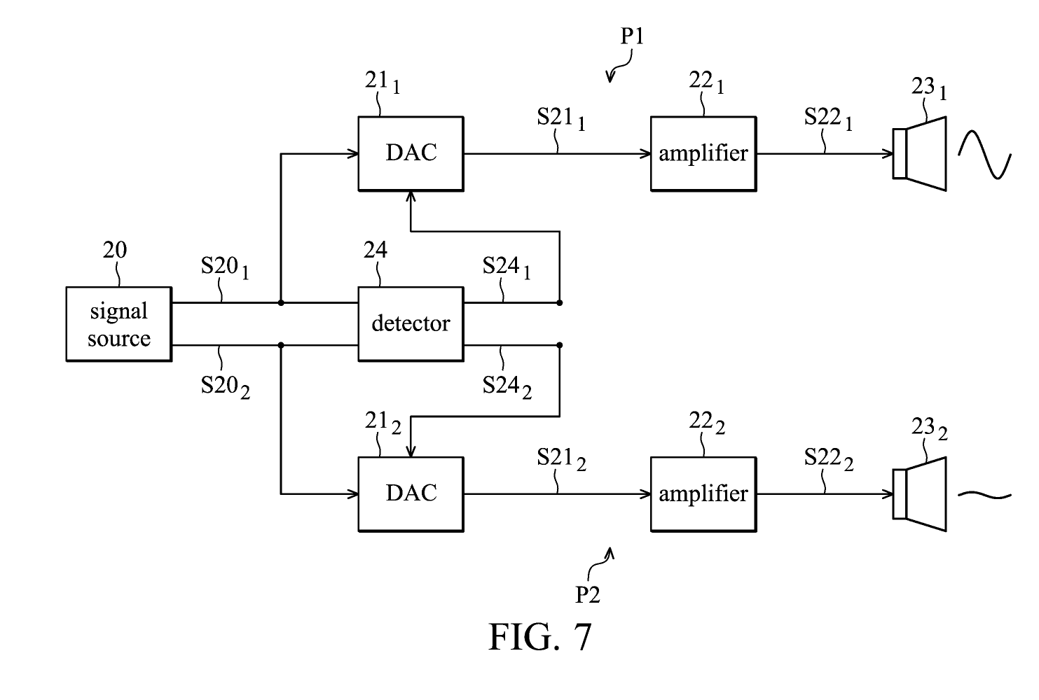

In some embodiments, the control signals S24₁ and S24₂ generated by the detector 24 can be used to only control the DACs 21₁ and 21₂, as shown in FIG. 7. In the above embodiments, according to system requirements, the control signals S24₁ and S24₂ generated by the detector 24 can be used to control the amplifier 22₁ and 22₂, the DACs 21₁ and 21₂, or both of the amplifier 22₁ and 22₂ and DACs 21₁ and 21₂.

While the invention has been described by way of example and in terms of the preferred embodiments, it is to be understood that the invention is not limited to the disclosed embodiments. To the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. An audio output device comprising:
a signal source for generating a plurality of digital signals;
a detector for receiving the digital signals and detecting states of the digital signals to generate a plurality of control signals according to the detection results respectively.
a plurality of digital-to-analog converters for receiving the digital signals and converting the digital signals to a plurality of analog signals, respectively; and
a plurality of amplifiers for receiving the analog signals and generating a plurality of amplified signals according to the control signals, respectively.

2. The audio output device as claimed in claim 1, wherein when the detector detects that at least one of the digital signals is in a predetermined state, the detector controls the corresponding amplifier according to the corresponding control signal to not generate the amplified signal.

3. The audio output device as claimed in claim 2, wherein when the detector detects that the at least one digital signal is in the predetermined state, the detector further controls the corresponding digital-to-analog converter according to the corresponding control signal to not generate the analog signal.

4. The audio output device as claimed in claim 2, wherein in the predetermined state, the at least one digital signal is at a constant logic level for a predetermined time.

5. The audio output device as claimed in claim 1, wherein the detector comprises a plurality of detection units for detecting the digital signals respectively, and each of the detection units comprises:
a plurality of delay circuits for receiving bits of the corresponding digital signal respectively, wherein each of the delay circuits generates a plurality of delay signals according to the corresponding bit; and
a logic gate for receiving the delay signals from the delay circuits and generating the corresponding control signal according to the received delay signals, wherein whether the corresponding amplifier generates the amplified signal is determined according to the control signal.

6. The audio output device as claimed in claim 5, wherein in each of the detection units, each of the delay circuits comprises:
a plurality of D-type flip-flops coupled in series and controlled by a clock signal,
wherein the first D-type flip-flop among the D-type flip-flops receives the corresponding bit, and the D-type flip-flops generate the corresponding delay signals in response to the corresponding bit respectively.

7. The audio output device as claimed in claim 5, wherein the logic gate is implemented by an exclusive OR (XOR) gate.

8. The audio output device as claimed in claim 5, wherein when at least one of the digital signals is in a predetermined state, the detector asserts the corresponding control signal to control the corresponding amplifier to not generate the amplified signal.

9. The audio output device as claimed in claim 8, wherein when the at least one digital signal is in the predetermined state, the detector controls the corresponding digital-to-analog converter to not generate the analog signal according to the asserted control signal.

10. The audio output device as claimed in claim 8, wherein in the predetermined state, the at least one digital signal is at a constant logic level for a predetermined time.

11. The audio output device as claimed in claim 1, wherein each of the amplifiers comprises:
a mute control unit controlled by the detector, wherein whether the mute control unit is enabled by the detector is determined according to the corresponding control signal; and
an amplifying unit for receiving the corresponding analog signal and amplifying the corresponding analog signal to generate the corresponding amplified signal;
wherein when the detector detects that at least one of the digital signals is in a predetermined state, the detector enables the mute control unit of the amplifier corresponding to the at least one digital signal through the corresponding control signal, and the amplifying unit of the corresponding amplifier is disabled by the enabled mute control unit and does not generate the corresponding amplified signal.

12. The audio output device as claimed in claim 1 further comprising a plurality of speakers for receiving the amplified signals and producing sound according to the amplified signals, respectively.
